(19) United States
(12) Patent Application Publication
(10) Pub. No.: US 2007/0090386 A1
(43) Pub. Date: Apr. 26, 2007

(54) AIR COOLED HIGH-EFFICIENCY LIGHT EMITTING DIODE SPOTLIGHT OR FLOODLIGHT

(75) Inventor: Richard Joel Petrocy, Carteret, NJ (US)

Correspondence Address: STANLEY H. KREMEN, 4 LENAPE LANE, EAST BRUNSWICK, NJ, 08816, US

(73) Assignee: UNIVERSAL MEDIA SYSTEMS, INC., Warren, NJ (US)

(21) Appl. No.: 11/552,029

(22) Filed: Oct. 23, 2006

Related U.S. Application Data
(60) Provisional application No. 60/596,809, filed on Oct. 21, 2005.

(51) Int. Cl. H01L 33/00

(52) U.S. Cl. 257/99

(57) ABSTRACT

The present invention replaces a standard size halogen tungsten lamp spotlight or floodlight with a much cooler LED lamp that also fits into existing housings. However, the LED's still need to be cooled. The Present Invention mounts up to three LED's into a special reflector with a plurality of specially designed heat sinking fins arranged in a star configuration. Peltier junctions may also be used to further direct heat to the fins.

### CROSS REFERENCE TO RELATED APPLICATIONS

This Present Application is the non-provisional counterpart of and claiming benefit of and priority to U.S. Provisional Application Ser. No. 60/596,809, filed Oct. 21, 2005, said U.S. Provisional Application being incorporated by reference herein in its entirety.

### BACKGROUND OF INVENTION

Currently, spotlights and floodlights comprise tungsten and tungsten-halogen lamps. These units are integrated with parabolic or elliptic type reflectors that fully or partially collimate the emitted light. Small units that are very bright use pinpoint tungsten-halogen bulbs mounted in plastic reflectors. Such a unit does not have to be hermetically sealed since it is separate from the bulb. However, tungsten-halogen lamps run very hot and use high amounts of electric current. Attempts have been made to replace these units with light emitting diodes (LED's). In November 2003, Ledtronics, Inc. released lighting units of various configurations comprising white 3,200° K. LED's ranging in size from the 3 mm midget flange up to 3.75 in. R-30-style spotlights. These devices use less electricity, and are therefore cheaper to run. However, they are not mounted inside of small reflectors, and they generate much heat. Running an LED at full power tends to crack the fragile LED lens due to heat stress.

### SUMMARY OF THE INVENTION

The present invention replaces a standard size halogen tungsten R-XX (where “XX” represents the model number) lamp with a much cooler LED lamp that also fits into existing housings. However, the LED's still need to be cooled. The Present Invention mounts up to three LED's into a special reflector with a plurality of specially designed heat sinking fins arranged in a star configuration. Peltier junctions may also be used to further direct heat to the fins.

### BRIEF DESCRIPTION OF THE DRAWINGS

FIG. 1 shows a front elevation view of a heat sink fin of the Present Invention. This represents the bottom fin in a three-fin assembly.

FIG. 2 shows a front elevation view of a second heat sink fin of the Present Invention. This represents the middle fin in a three-fin assembly.

FIG. 3 shows a front elevation view of a third heat sink fin of the Present Invention. This represents the top fin in a three-fin assembly.

FIG. 4 shows a top plan view of the three fins arranged in a six-point star configuration.

FIG. 5 shows front elevation and top plan views of the fins having serrated edges.

FIG. 6 shows a cross sectional view of an LED lamp assembly.

FIG. 7 shows a bottom plan view of the lamp assembly of FIG. 6.

FIG. 8 shows a schematic of a lamp comprising three LED's.

### DETAILED DESCRIPTION OF THE INVENTION

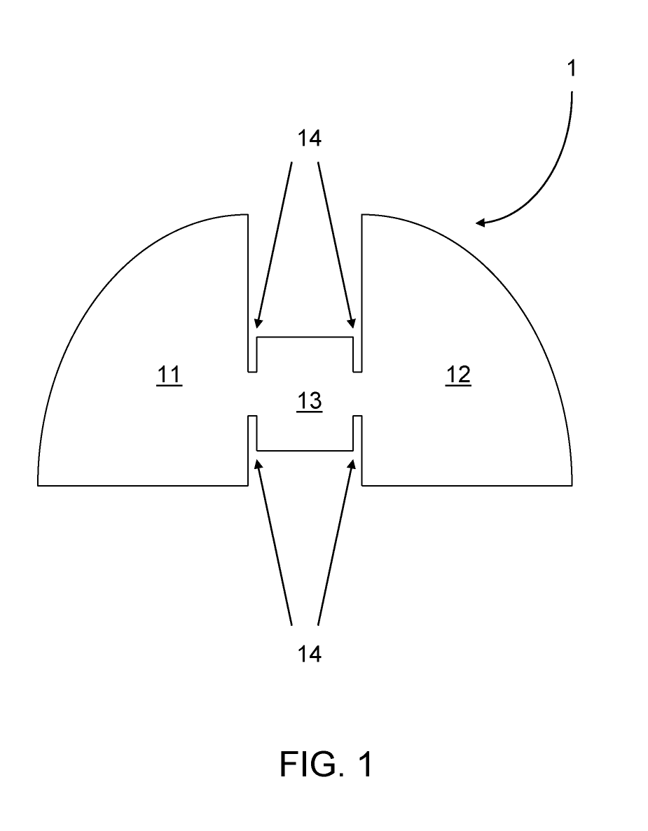

FIG. 1 shows a front elevation view of a heat sink fin assembly, 1, of the Present Invention. This represents the bottom fin in a three-fin assembly. The outer edges of fins 11 and 12 have the same shape as the reflector (e.g., parabolic, elliptical, etc.) and are sized to fit inside the reflector with minimal clearance. Accordingly, they are separated by area 13, the size of which insures that the assembly fits snuggly into the interior of the reflector. Four slits 14 are present to allow the other fin assemblies to be inserted therein.

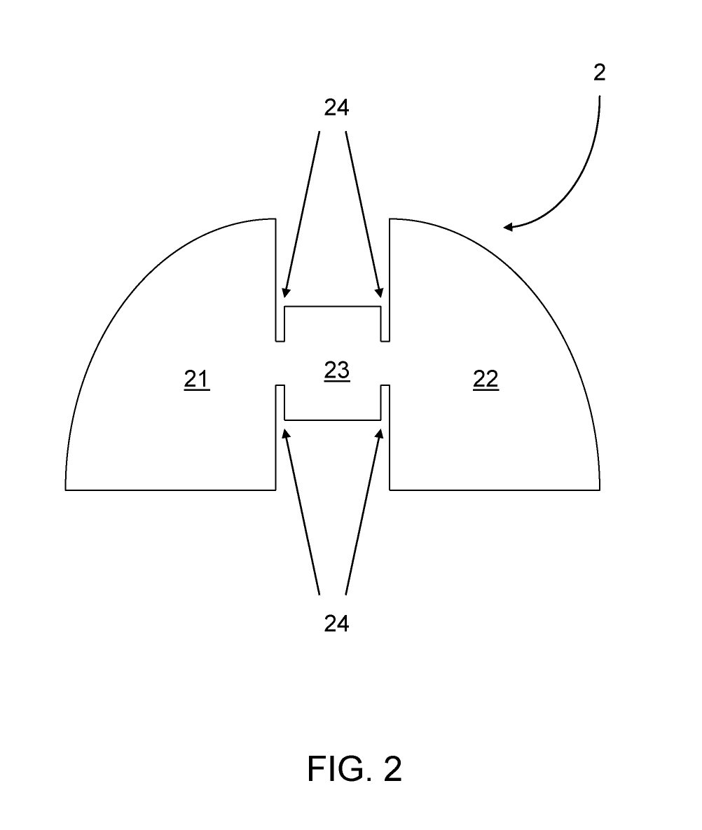

FIG. 2 shows the middle heat sink fin assembly, 2, of the Present Invention. The outer edges of fins 21 and 22 have the same shape as the outer edges of fins 11 and 12 of the bottom fin assembly, respectively. The middle area 23 is the same size as 13 in the bottom assembly. Four slits 24 are present to allow the other fin assemblies to be inserted therein.

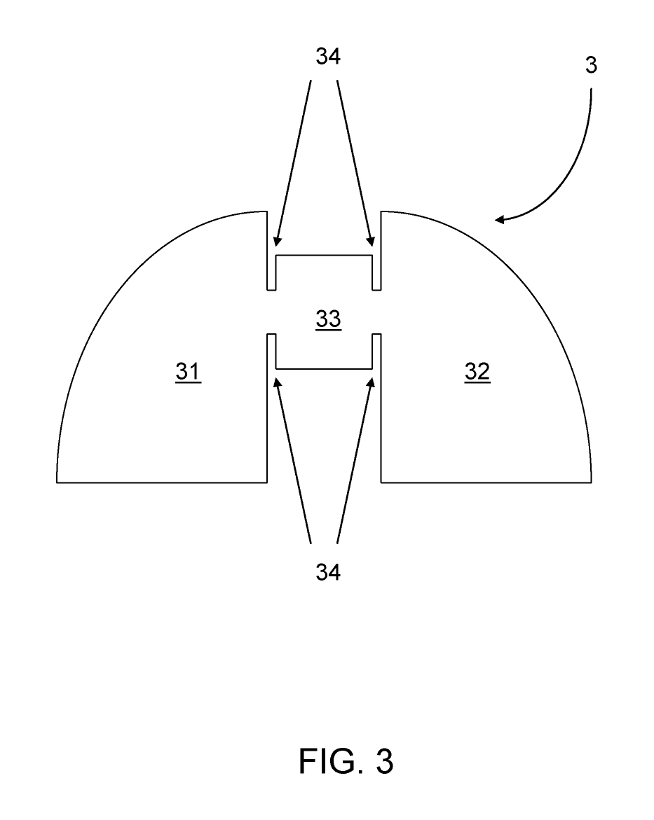

FIG. 3 shows the middle top sink fin assembly, 2, of the Present Invention. The outer edges of fins 31 and 32 have the same shape as the outer edges of fins 11 and 12 of the bottom fin assembly, respectively. The middle area 33 is the same size as 13 in the bottom assembly. Four slits 34 are present to allow the other fin assemblies to be inserted therein.

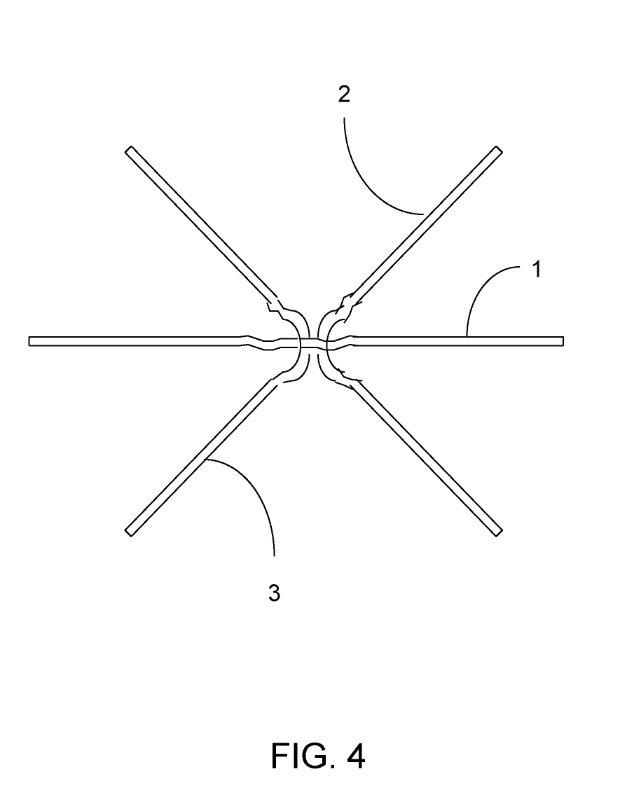

FIG. 4 shows a top plan view of the three fins arranged in a six-point star configuration. The material comprising each fin assembly (preferably thin sheet metal) must be flexible enough to bend upon assembly, but cannot be so flexible as not to hold its shape when assembled.

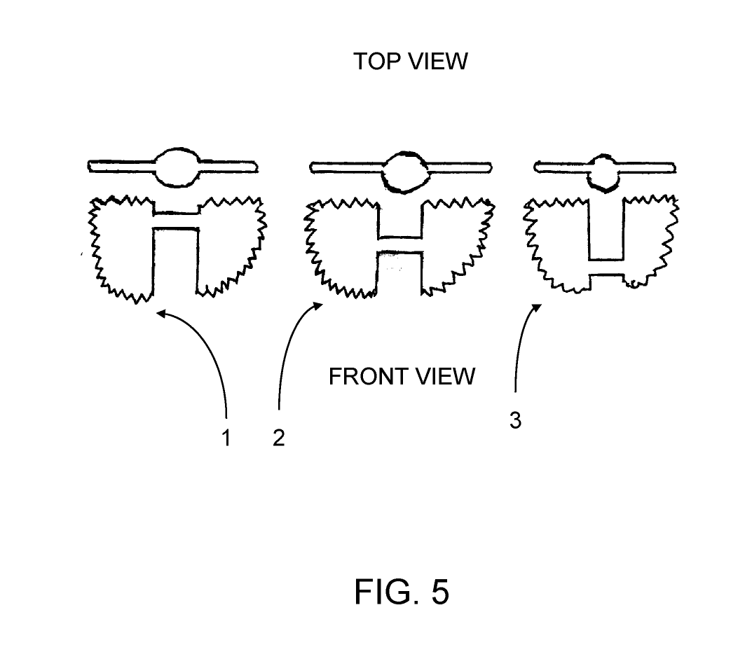

FIG. 5 shows that the fins may have serrated edges on any surface to provide greater heat dissipation.

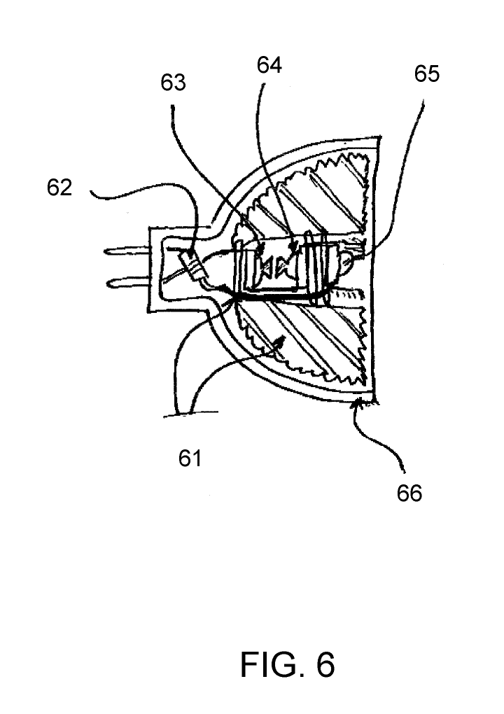

FIG. 6 shows a cross sectional view of an LED lamp assembly. A heat sink cooling fin assembly 61 such as is shown in FIG. 4 or FIG. 5 surrounds LED's 63, 64, and 65 that are stacked in-line, one on top of the other. 63 represents the LED on the bottom of the stack, 64 represents the middle LED, and 65 represents the LED on the top of the stack. A resistor 62 is placed in the circuit. Reflector lens 66 collimates the light from the three LED's, either completely or partially, to produce the light output.

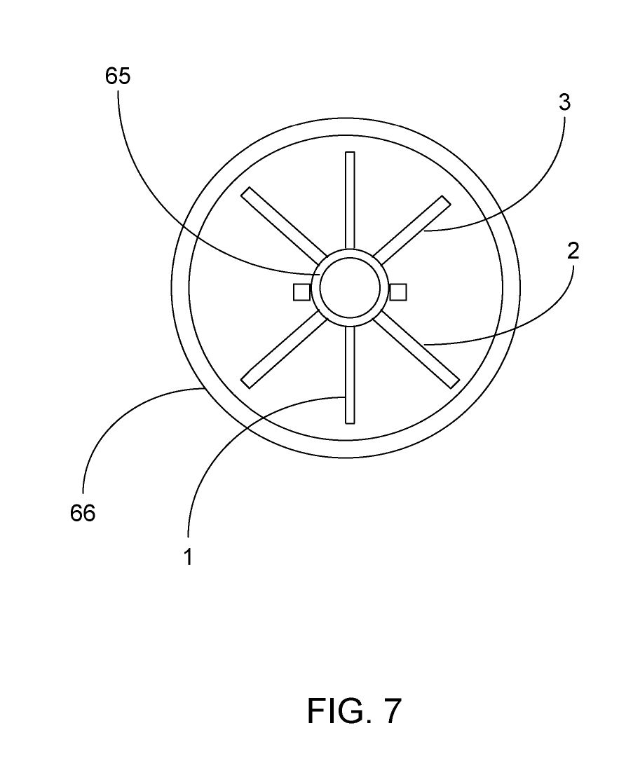

FIG. 7 shows a bottom plan view of the lamp assembly of FIG. 6. The lens of LED 65, the LED at the top of the stack, is visible. The six-point star configuration of the cooling fins 1, 2, and 3 is plainly visible.

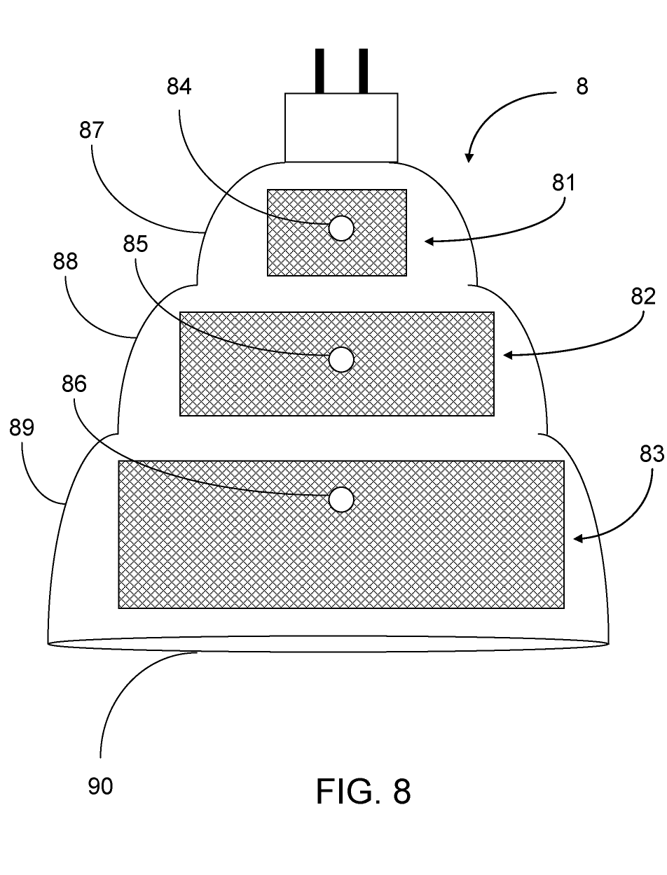

FIG. 8 is a schematic showing how three LED's configured into a linear stack can produce either fully or partially collimated light. Lamp assembly 8 comprises a housing having multiple reflectors 87, 88, and 89; and three LED assemblies 81, 82, and 83 each having heat sink cooling fins (not shown) with LED's 84, 84, and 86, respectively. The reflectors 87, 88, and 89 are joined as shown, and they have different focal points. LED 84 is positioned at the focal point of reflector 87; LED 85 is positioned at the focal point of reflector 88; and, LED 86 is positioned at the focal point of reflector 89. In this way, collimated light emanating from LED's 84, 85, and 86, is combined and emanates from lamp assembly 8. Optionally, lens 90 may be positioned so as to further define the output light distribution.

Peltier thermocouples may be used to direct heat away from the LED's to the cooling fins to enhance the cooling effect.

I claim:

1. A lighting assembly for use as a spotlight or floodlight comprising:
at least one light emitting diode;
electronics that cause the diode to emit light;
a plurality of heat sink fins that are in contact with the diode and cool the diode;
at least one optical element that concentrates the light emitted from said at least one diode; and,
a housing that contains said at least one diode, the electronics, the heat sink fins, and said at least one optical element.

2. The lighting assembly of claim 1 wherein the heat sink fins have serrated edges.

3. The lighting assembly of claim 1 wherein the heat sink fins further surround the diode in such a manner that they are all equidistant from one another.

4. The lighting assembly of claim 3 wherein the plurality of heat sink fins consists of an even number of fins.

5. The lighting assembly of claim 4 wherein the fins are arranged in a plurality of pairs such that each fin of the pair of fins is positioned on opposite sides of the diode.

6. The lighting assembly of claim 5 wherein the two fins of each pair of fins is combined into a single unit cooling fin assembly.

7. The lighting assembly of claim 6 wherein the plurality of pairs surrounds the diode and is configured as a star, with each fin being an extension of the star.

8. The lighting assembly of claim 1 further comprising a plurality of diodes arranged such that light emitted from each diode of the plurality incrementally adds to the total light emitted by the lighting assembly.

9. The lighting assembly of claim 8 wherein each diode of the plurality comprises an optical element that concentrates the light emitted from that diode, thereby forming a plurality of optical elements of the same number as the number of diodes.

10. The lighting assembly of claim 9 wherein the plurality of diodes has a linear arrangement.

11. The lighting assembly of claim 9 wherein the optical element for each diode is a reflector.

12. The lighting assembly of claim 10 wherein the optical element for each diode is a reflector.

13. The lighting assembly of claim 12 wherein the reflector optical element for each diode focuses light to a focal point.

14. The lighting assembly of claim 13 wherein each diode is positioned at the focal point of its respective reflector optical element thereby producing collimated light.

15. The lighting assembly of claim 14 wherein the focal lengths of the reflector optical elements are different and wherein the diodes with their associated reflector optical elements are arranged so that the collimated light emitted from the reflector optical elements combine to produce a light intensity greater than that which would be obtainable from a single diode and single reflector optical element.

16. A lighting assembly for use as a spotlight or floodlight comprising:
at least one light emitting diode;
a means for causing the diode to emit light;
a means for air cooling the diode;
at least one means for concentrating the light emitted from said at least one diode; and,
a means for containing said at least one diode, said means for causing the diode to emit light, said means for cooling, and said at least one means for concentrating the light.

17. The lighting assembly of claim 16 further comprising a plurality of diodes and a plurality of means for concentrating the light, wherein each diode is associated with a single means for concentrating the light.

18. The lighting assembly of claim 17 wherein:
each of the means for concentrating the light concentrates the light emitted from its associated diode to a different point in space;
each diode is arranged with respect to its associated means for concentrating such that light emitting from the means for concentrating is collimated; and,
collimated light emitted from all the means for concentrating the light combines to produce a light intensity greater than that which would be obtainable from a single diode and single means for concentrating the light.
